(19) United States
(12) Patent Application Publication
(10) Pub. No.: US 2015/0295070 A1
(43) Pub. Date: Oct. 15, 2015

(54) FINFET AND METHOD FOR MANUFACTURING THE SAME

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 14/441,114

(22) PCT Filed: Nov. 30, 2012
(86) PCT No.: PCT/CN2012/085625

§ 371 Date: May 6, 2015

(30) Foreign Application Priority Data
Nov. 16, 2012 (CN) 201210464915.9

(51) Int. Cl. H01L 29/66; H01L 29/78

(52) U.S. Cl. CPC H01L 29/66795; H01L 29/785; H01L 29/7848

(57) ABSTRACT

A FinFET and a method for manufacturing the same. The method of manufacturing a FinFET includes: forming a punch-through stopper layer on a semiconductor substrate; forming a first semiconductor layer on the punch-through stopper layer; forming source and drain regions in the first semiconductor layer; forming a semiconductor fin from the first semiconductor layer, wherein the source and drain regions are in contact with the semiconductor fin at opposite ends of the semiconductor fin, respectively; and forming a gate stack intersecting the semiconductor fin and including a gate conductor and a gate dielectric interposed between the gate conductor and the semiconductor fin.

### CROSS-REFERENCE TO RELATED APPLICATION(S)

This application is a U.S. national phase application of PCT Application No. PCT/CN2012/085625, filed on Nov. 30, 2012, entitled “FinFET AND METHOD FOR MANUFACTURING THE SAME, which claimed priority to Chinese Application No. 201210464915.9, filed on Nov. 16, 2012, both of which are incorporated herein by reference in their entireties.

### TECHNICAL FIELD

The present disclosure generally relates to the semiconductor technology, and more particularly, to a fin Field Effect Transistor (FinFET) and a method of manufacturing the same.

### BACKGROUND

An important trend in development of the Integrated Circuit (IC) technology is scaling down of Metal-Oxide-Semiconductor Field Effect Transistors (MOSFETs) for improving integration level and reducing manufacturing cost. However, it is well known that short channel effects arise as the size of MOSFETs decreases. As MOSFETs are scaled down, a gate also has a reduced effective length, and thus actually controls fewer charges in a depletion region when a gate voltage is applied. Consequently, a threshold voltage of MOSFETs drops with a reduced channel length. When the gate length is reduced to about 30 nm, short channel effects cannot be avoided in conventional MOSFETs.

To suppress short channel effects, U.S. Pat. No. 6,413,802 discloses a FinFET formed on an SOI substrate, which comprises a channel region provided in a central portion of a fin of semiconductor material, and source/drain regions provided at opposite ends of the fin. A gate electrode is provided on opposite sides of the channel region to surround the latter (i.e., a double-gate configuration), in which inversion layers are created at both sides of the channel. The channel region in the fin has a small thickness so that the whole channel region is controlled by the gate, which facilitates suppressing the short channel effects.

Mobility of carriers can be improved by applying appropriate stress to the channel region of the MOSFET, so as to reduce an ON resistance and thus enhancing a switching speed of the device. When the device is an n-type MOSFET, it is desirable to apply tensile stress to the channel region in a longitudinal direction of the channel region, and to apply compressive stress to the channel region in a lateral direction of the channel region, so as to improve the mobility of electrons as carriers. On the other hand, when the device is a p-type MOSFET, it is desirable to apply compressive stress to the channel region in the longitudinal direction of the channel region, and to apply tensile stress to the channel region in the lateral direction of the channel region, so as to improve the mobility of holes as carriers.

Desirable stress can be created by using a semiconductor material different from that of the substrate to form source and drain regions. For the n-type MOSFET, the source and drain regions of Si:C formed on the substrate of Si can result in tensile stress applied to the channel region in the longitudinal direction of the channel region. On the other hand, for the p-type MOSFET, the source and drain regions of SiGe formed on the substrate of Si can result in compressive stress applied to the channel region in the longitudinal direction of the channel region. The source and drain regions, as the supplier of the stress, should have a certain volume to create the required stress. Therefore, bulk silicon substrates are generally used in stress enhanced MOSFETs.

It is desirable to form a FinFET on bulk silicon and to further improve device performances thereof by means of stress.

### SUMMARY

The present disclosure aims to provide, among others, a stress enhanced FinFET and a method of manufacturing the same.

According to an aspect of the present disclosure, there is provided a method of manufacturing a FinFET, comprising: forming a punch-through stopper layer on a semiconductor substrate; forming a first semiconductor layer on the punch-through stopper layer; forming source and drain regions in the first semiconductor layer; forming a semiconductor fin from the first semiconductor layer, wherein the source and drain regions are in contact with the semiconductor fin at opposite ends of the semiconductor fin, respectively; and forming a gate stack intersecting the semiconductor fin and including a gate conductor and a gate dielectric interposed between the gate conductor and the semiconductor fin.

According to embodiments of the present disclosure, there is provided a FinFET, comprising: a semiconductor substrate; a punch-through stopper layer disposed on the semiconductor substrate; a semiconductor fin disposed on the punch-through stopper layer; source and drain regions disposed on the punch-through stopper layer and being in contact with the semiconductor fin at opposite ends of the semiconductor fin, respectively; and a gate stack disposed on top and side walls of the semiconductor fin and including a gate conductor and a gate dielectric interposed between the gate conductor and the semiconductor fin.

According to the process proposed herein, the FinFET is manufactured in a fin-last process, in which the source and drain regions are formed before the semiconductor fin and the gate stack are formed. With the process, it is possible to integrate high-K gate dielectric and metal gate into the FinFET, to suppress short channel effects of the device. This facilitates integration of the high-k gate dielectric and the metal gate and also the source and drain regions as stress supplier, so as to improve device performances. Further, it is possible to apply different stress to the semiconductor fin for different types of devices by using a different material from that of the semiconductor fin to form the source and drain regions in contact with opposite ends of the semiconductor fin, so as to improve mobility of channel carriers.

### BRIEF DESCRIPTION OF THE DRAWINGS

FIGS. 1-9 are schematic views showing semiconductor structures in some stages of a process of manufacturing a FinFET according to an embodiment of the present disclosure, wherein FIGS. 1-4, 5b-9b are cross-sectional views along a longitudinal direction of a channel region, FIGS. 5c-9c are cross-sectional views along a lateral direction of the channel region, and FIGS. 5a-9a are top views of the respective semiconductor structures.

### DETAILED DESCRIPTION

Embodiments of the present disclosure will be described in more details below with reference to the accompanying drawings. In the drawings, like reference numerals denote like elements. The figures are not drawn to scale, for the sake of clarity.

For simplicity, the structure of a semiconductor device having been subjected to several relevant process steps may be shown in one figure.

It should be understood that when one layer or region is referred to as being “above” or “on” another layer or region in describing the device structure, it can be directly above or on the other layer or region, or other layers or regions may be intervened therebetween. Moreover, if the device in the figures is turned over, the layer or region will be “under” or “below” the other layer or region.

In contrast, when one layer is referred to as being “directly on” or “on and adjacent to” or “adjoin” another layer or region, there are no intervening layers or regions present.

In the present application, the term “semiconductor structure” generally means the whole semiconductor structure formed at various steps during manufacture of the semiconductor device, including all layers and regions having been formed. The term “a longitudinal direction of a channel region” refers to a direction from a source region to a drain region or vice versa. The term “a lateral direction of a channel region” refers to a direction perpendicular to the longitudinal direction of the channel region in a plane parallel to a main surface of a semiconductor substrate. For example, for a MOSFET formed on a silicon wafer of (100), the longitudinal direction of the channel region is generally in a <110> direction of the silicon wafer, and the lateral direction of the channel region is generally in a <011> direction of the silicon wafer.

Some particular details of the present disclosure will be described below, such as exemplary semiconductor structures, materials, dimensions, process steps and technologies of the semiconductor device, for better understanding of the present disclosure. However, it is to be understood by one skilled person in the art that those details are not always essential for but can be varied in a specific implementation of the disclosure.

Unless the context clearly indicates otherwise, each part of a MOSFET can be made of material(s) well-known to one skilled person in the art. The semiconductor material includes, for example, Group III-V semiconductor, such as GaAs, InP, GaN and SiC, and Group IV semiconductors, such as Si and Ge. A gate conductor may be made of any conductive material, such as metal, doped polysilicon, and a stack of metal and doped polysilicon, among others. For example, the gate conductor may be made of one selected from a group consisting of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni₃Si, Pt, Ru, Ir, Mo, HfRu, RuOx, and their combinations. A gate dielectric layer may be made of SiO₂ or other dielectric insulation material which has a dielectric constant larger than that of SiO₂, such as oxide, nitride, oxynitride, silicate, aluminate, and titanate. The oxide includes, for example, SiO₂, HfO₂, ZrO₂, Al₂O₃, TiO₂, La₂O₃. The nitride includes, for example, Si₃N₄. The silicate includes, for example, HfSiOx. The aluminate includes, for example, LaAlO₃. The titanate includes, for example, SrTiO₃. The oxynitride includes, for example, SiON. Moreover, the gate dielectric layer may be made of those developed in the future, besides the above known materials.

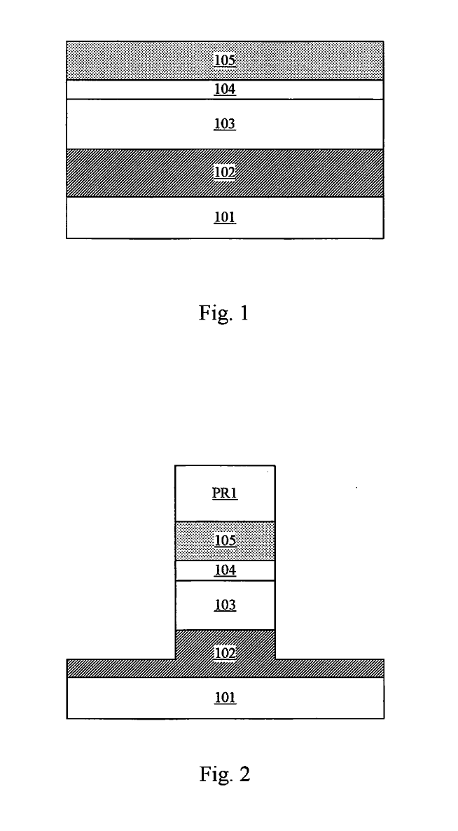

According to an embodiment of the present disclosure, various stages as shown in FIGS. 1 to 9 are performed to make a stress-enhanced FinFET. Cross-sectional views of the semiconductor structures at various stages are given in these figures. Further, top views are shown, if necessary, where line AA indicates a cutting position along the longitudinal direction of the channel region, and line BB indicates a cutting position along the lateral direction of the channel region.

The method starts with the semiconductor structure as shown in FIG. 1. Specifically, on a semiconductor substrate 101, a punch-through stopper layer 102, a first semiconductor layer 103, a first oxide layer 104 and a first nitride layer 105 are formed sequentially. For example, the semiconductor substrate 101 may comprise Si. The semiconductor substrate 101 may be subjected to well-implantation and well-annealing, if necessary. The punch-through stopper layer 102 may comprise a doped semiconductor material, with a thickness of about 10-50 nm. The first semiconductor layer 103 will be used to form a semiconductor fin, and may comprise Si, with a thickness of about 20-100 nm. The first oxide layer 104 may comprise silicon oxide, with a thickness of about 2-10 nm. The first nitride layer 105 may comprise silicon nitride, with a thickness of about 50-150 nm. As known in the art, the first oxide layer 104 can alleviate stress between the semiconductor substrate 101 and the first nitride layer 105. The nitride layer 105 is used as a stop layer for Chemical Mechanical Polishing (CMP) in a subsequent etching process and also as a hard mask for the etching.

The respective layers as described above may be formed in known processes. For example, the punch-through stopper layer 102 and the first semiconductor layer 103 may be formed by deposition, such as Electron Beam evaporation (EBM), Chemical Vapor Deposition (CVD), Atom Layer Deposition (ALD), and sputtering. The first oxide layer 104 may be formed by thermal oxidation, for example. Further, the first nitride layer 105 may be formed by CVD.

In a further embodiment, the punch-through stopper layer 102 is a semiconductor layer of, e.g., Si or SiGe, epitaxially grown on the semiconductor substrate 101. The punch-through stopper layer 102 may be doped in-situ to a doping concentration of, e.g., 1e18-2e19/cm³. N-type dopants, such as As or P, are used for a p-type FinFET, while p-type dopants, such as In, BF₂ or B, are used for an n-type FinFET. The punch-through stopper layer 102 has a doping type contrary to that of source and drain regions, and thus can block a current leakage path via the semiconductor substrate 101 between the source and drain regions of the FinFET.

Then, a photo-resist layer PR1 is formed on the first nitride layer 105 by spin coating, and then patterned into a pattern to define a longitudinal dimension (i.e., length) of a semiconductor fin to be formed by photolithography, including exposure and development. Exposed portions of the first nitride layer 105, the first oxide layer 104 and the first semiconductor layer 103 are removed sequentially from top down by dry etching, such as ion milling, plasma etching, Reactive Ion Etching (RIE), or laser ablation, or wet etching with an etchant solution, with the photo-resist layer PR1 as a mask. During the etching, the punch-through stopper layer 102 may have a portion thereof also removed. For example, the etching duration may be controlled so that the etching is stopped at a certain depth into the punch-through stopper layer 102, as shown in FIG. 2. The photo-resist layer PR1 may be removed by being solved in a solvent or being ashed.

Due to the etching, openings for the source and drain regions are formed. It is to be noted that the semiconductor structures shown in FIG. 2 and subsequent figures show only a fraction of the semiconductor substrate 101, for example, a fraction in an active region surrounded by Shallow Trench Isolation (STI, not shown). As understood by those skilled in the art, the etching results in trenches or openings in the semiconductor structure, though the semiconductor structure looks like a step in the figure.

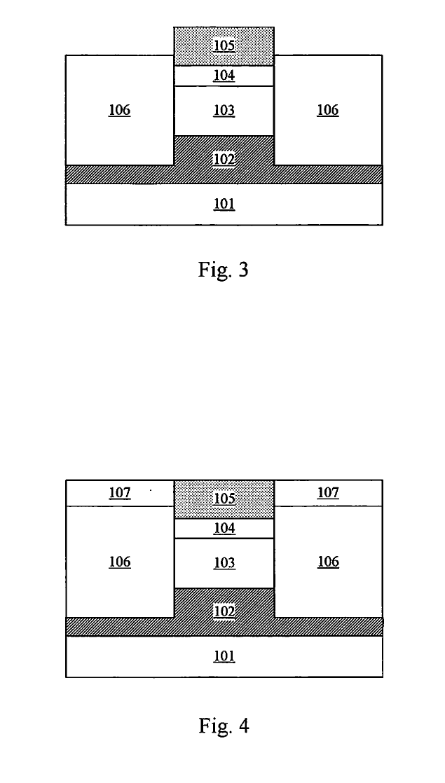

After that, a second semiconductor layer 106 may be formed in the openings by a known deposition process, as shown in FIG. 3. Preferably, the second semiconductor layer 106 may comprise a semiconductor layer epitaxially grown only within the openings and filling the openings to some extent. Alternatively, the second semiconductor layer 106 may comprise a blanket layer formed on the semiconductor structure to fill into the openings and then have portions thereof outside the openings removed by CMP with the first nitride layer 105 as a stop layer, and then be etched back so that it fills the openings to some but not full extent.

The second semiconductor layer 106 includes two sections on opposite sides of the first semiconductor layer 103, where the source and drain regions of the FinFET are to be formed respectively. Further, the second semiconductor layer 106 comprises a different material from that of the first semiconductor layer 103, so that it can apply stress to the semiconductor fin to be formed. For example, the second semiconductor layer 106 may comprise SiGe for a p-type FinFET with an atomic percentage of Ge of about 15-75%, while Si:C for an n-type FinFET with an atomic percentage of C of about 0.5-2%.

The second semiconductor layer 106 has side surfaces abutting respective side surfaces of the first semiconductor layer 103, so that it can apply appropriate stress to the channel region in the first semiconductor layer 103. Preferably, the second semiconductor layer 106 may have its top surface substantially flush with or higher than that of the first semiconductor layer 103, to maximize a contact area with the first semiconductor layer 103, so as to maximize the stress effect.

Subsequently, a second oxide blanket layer 107 may be formed on the semiconductor substrate by a known deposition process, and then have portions thereof outside the openings removed by CMP with the first nitride layer 105 as a stop layer, so that the second oxide layer 107 fills up the openings, as shown in FIG. 4.

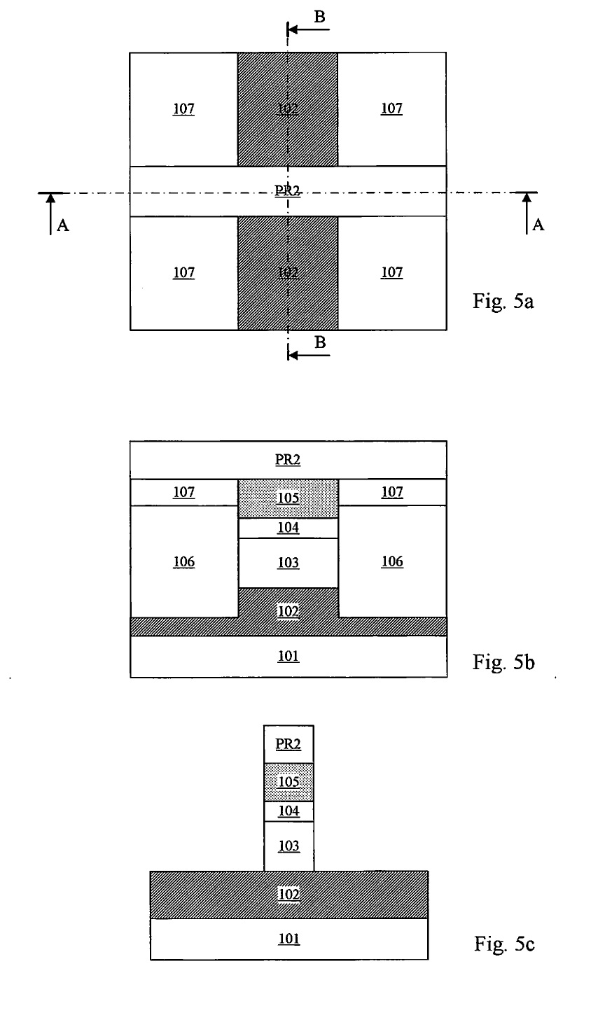

Next, a photo-resist layer PR2 is formed on the semiconductor structure by spin coating, and then patterned into a pattern to define a lateral dimension (i.e., width) of the semiconductor fin to be formed by photolithography, including exposure and development. Exposed portions of the first nitride layer 105, the first oxide layer 104 and the first semiconductor layer 103 are removed sequentially from top down by dry etching, such as ion milling, plasma etching, RIE, or laser ablation, or wet etching with an etchant solution, with the photo-resist layer PR2 and the second oxide layer 107 as a mask. The etching may be stopped at the top of the punch-through stopper layer 102, as shown in FIGS. 5a, 5b, and 5c. The photo-resist layer PR2 may be removed by being solved in a solvent or being ashed.

It is to be noted that the second oxide layer 107 can be used as a hard mask in the etching due to a relatively slow etching rate thereof. However, the second oxide layer 107 may have its thickness reduced by being partially etched.

The etching results in the semiconductor fin from the first semiconductor layer 103. This etching not only defines the width of the semiconductor fin, but also results in openings that expose side walls of the semiconductor fin. As described above, the etching results in trenches or openings in the semiconductor structure, though the semiconductor structure looks like a step in FIG. 5c. The semiconductor fin has its opposite ends in contact with the source and drain regions formed in the second semiconductor layer 106, respectively. The first oxide layer 104 and the first nitride layer 105 are positioned on top of the semiconductor fin.

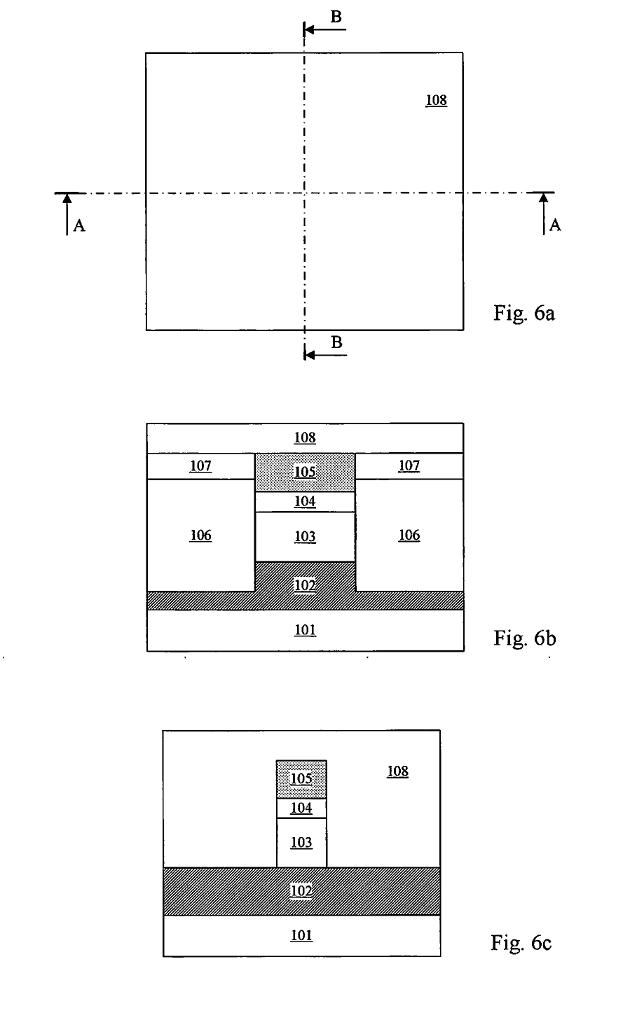

After that, a second nitride blanket layer 108 may be formed on the semiconductor structure by a known deposition process, and then subjected to CMP to have a flat surface, as shown in FIGS. 6a, 6b and 6c.

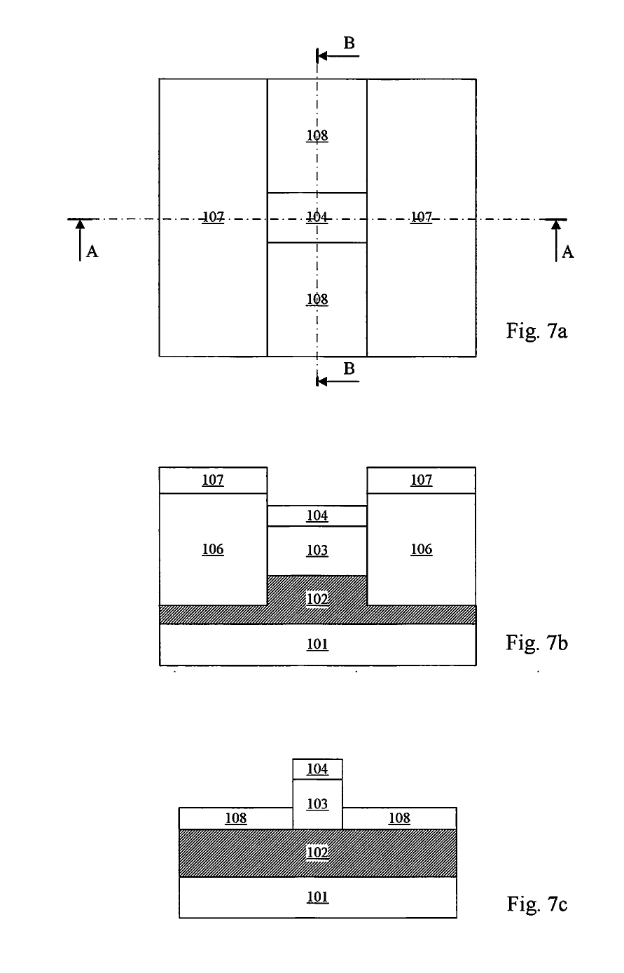

Next, a portion of the second nitride layer 108 may be removed by selective dry or wet etching with respect to the first oxide layer 104 and the second oxide layer 107, without using a mask, as shown in FIGS. 7a, 7b and 7c. The second nitride layer 108 is left at the bottom of the openings to fill the openings to some but not full extent. The etching further removes the first nitride layer 105 underlying the second nitride layer 108, so as to expose the top of the semiconductor fin.

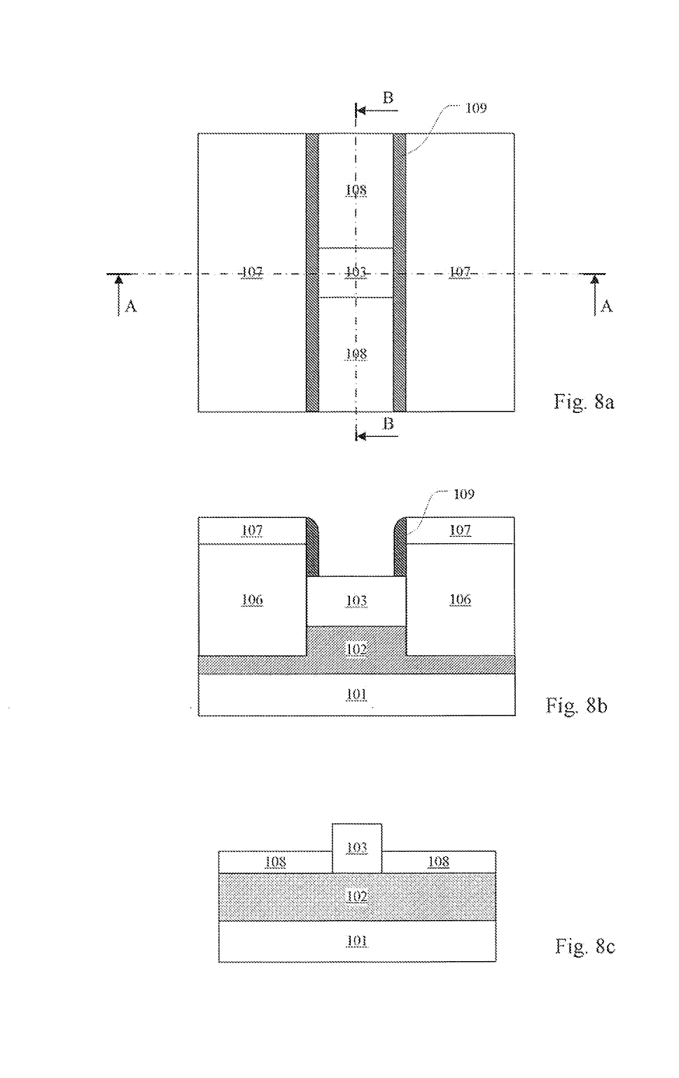

Subsequently, a third oxide layer may be formed on the semiconductor structure in a conformal way by a known deposition process. The third oxide layer may comprise silicon oxide, with a thickness of about 5-10 nm. The third oxide layer may be etched anisotropically by, e.g., RIE, with the second nitride layer 108 as a stop layer, so that only portions of the third oxide layer on side walls of the second semiconductor layer 106 and the second oxide layer 107 are left, resulting in a gate spacer 109, as shown in FIGS. 8a, 8b and 8c. The thickness of the first semiconductor layer 103 (i.e., a height of the side wall of the fin) is significantly less than the height of exposed portions of the side walls of the second semiconductor layer 106 and the second oxide layer 107 within the openings. As a result, portions of the third oxide layer on the side walls of the fin can be completely removed in the anisotropic etching of the third oxide layer. Further, the second oxide layer 107 may have its thickness reduced by being partially etched in the etching.

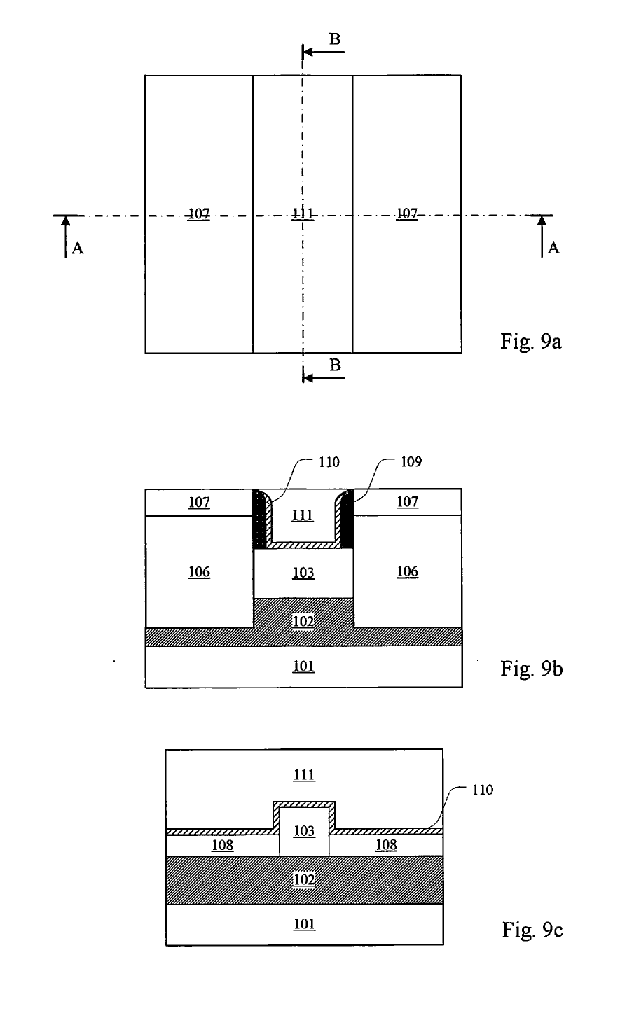

Then, a conformal dielectric layer and a blanket gate material layer may be formed sequentially on the semiconductor structure by known deposition processes. The dielectric layer covers at least the top and side walls of the semiconductor fin. The dielectric layer may comprise a high-K material, preferably HfO₂, with a thickness of about 2-4 nm. The gate material layer has a thickness sufficient to fill up the openings. Next, portions of the dielectric layer and the gate material layer outside the openings may be removed by CMP with the second oxide layer 107 as a stop layer, resulting in a gate stack including a gate dielectric 110 and a gate conductor 111, as shown in FIGS. 9a, 9b and 9c. The gate conductor 111 is positioned on the top and side walls of the semiconductor fin made from the first semiconductor layer 103, with the gate dielectric 110 interposed therebetween. The gate conductor 111 extends in the width direction of the semiconductor fin, and is separated from the source and drain regions in the second semiconductor layer 106 by the gate spacer 109 and also separated from the punch-through stopper layer 102 by the second nitride layer 108 as an isolation layer.

Preferably, a conformal threshold adjustment metal layer (not shown) may be further formed between the dielectric layer and the gate material layer, to further adjustment a threshold voltage of the FinFET. The threshold adjustment metal layer may comprise any one selected from TaN, TaAlN, or TiAlN, with a thickness of about 3-15 nm.

After the process shown in FIGS. 9a, 9b and 9c, an interlayer insulation layer, through-holes passing through the interlayer insulation layer to the source and drain regions in the second semiconductor layer 106 and to the gate conductor 111, wirings or electrodes on an upper surface of the interlayer insulation layer may be formed on the semiconductor structure, to complete the FinFET.

In the above embodiment, the stress-enhanced p-type MOSFET and also the material as a stress supplier therefore are illustrated. However, the inventive concept is also applicable to the stress-enhanced n-type MOSFET. In the n-type MOSFET, the semiconductor substrate 101 may comprise Si, the first semiconductor layer 101 may comprise Si, and the second semiconductor layer 106 may comprise Si:C, which is used to form the source and drain regions therein, and serves as a stress supplier to apply tensile stress to the channel region in the longitudinal direction of the channel region. The stress-enhanced n-type MOSFET may be manufactured in a similar way to that described above, except that the material of the stress supplier is different.

In the above embodiment, the first oxide layer 104, the second oxide layer 107 and the third oxide layer for forming the gate spacer 109, and also the first nitride layer 105 and the second nitride layer 108 are illustrated. However, those oxide layers and nitride layers can be interchanged. That is, the first oxide layer 104, the second oxide layer 107 and the third oxide layer may be substituted by nitride, while the first nitride layer 105 and the second nitride layer 108 may be substituted by oxide.

Further, it is to be understood that those oxide and nitride layers can be substituted by various insulating layers in alternative embodiments. That is, the first oxide layer 104, the second oxide layer 107 and the third oxide layer may be substituted by a first insulating material, while the first nitride layer 105 and the second nitride layer 108 may be substituted by a second insulating material, as long as that the first insulating material and the second insulating material have different etching rates so that the second insulating material can be selectively removed with respect to the first insulating material and the first insulating material can be selectively removed with respect to the second insulating material.

The above descriptions are provided to illustrate the inventive concept only, but not intended to limit the present disclosure. Therefore, the present disclosure is not limited to the embodiments. Variations and changes apparent to those skilled in the art fall in the scope of the present disclosure.

1. A method of manufacturing a FinFET, comprising:
forming a punch-through stopper layer on a semiconductor substrate;
forming a first semiconductor layer on the punch-through stopper layer;
forming source and drain regions in the first semiconductor layer;
forming a semiconductor fin from the first semiconductor layer, wherein the source and drain regions are in contact with the semiconductor fin at opposite ends of the semiconductor fin, respectively; and
forming a gate stack intersecting the semiconductor fin and including a gate conductor and a gate dielectric interposed between the gate conductor and the semiconductor fin.

2. The method of claim 1, wherein the punch-through stopper layer comprises an epitaxial layer on the semiconductor substrate, and is doped in-situ into a doping type contrary to that of the source and drain regions.

3. The method of claim 2, wherein the punch-through stopper layer has a doping concentration of about 1e18-2e19/cm³.

4. The method of claim 1, wherein forming the source and drain regions comprises:
etching the first semiconductor layer to form first openings arriving at the punch-through stopper layer; and
epitaxially growing a semiconductor material in the openings to form the source and drain regions.

5. The method of claim 4, wherein the first openings define a length of the semiconductor fin, and forming the semiconductor fin comprise:
etching the first semiconductor layer to form a second opening arriving at the punch-through stopper layer, so as to form the semiconductor fin, wherein the second opening defines a width of the semiconductor fin.

6. The method of claim 5, wherein between formation of the semiconductor fin and formation of the gate stack, the method further comprises:
forming an isolation layer at bottom of the second opening.

7. The method of claim 5, wherein forming the gate stack comprises:
forming a gate spacer on side walls of the second opening adjacent to the source and drain regions;
forming a gate dielectric on top and side walls of the semiconductor fin within the second opening; and
forming a gate conductor on the gate dielectric.

8. The method of claim 1, wherein the semiconductor fin comprises a first semiconductor material, and the source and drain regions comprise a second semiconductor material different from the first semiconductor material, so that the source and drain regions apply stress to the semiconductor fin along a longitudinal direction of the semiconductor fin.

9. The method of claim 8, wherein the FinFET is of p-type, and wherein the first semiconductor material comprise Si, and the second semiconductor material comprises SiGe, with an atomic percentage of Ge of about 15-75%.

10. The method of claim 8, wherein the FinFET is of n-type, and wherein the first semiconductor material comprise Si, and the second semiconductor material comprises Si:C, with an atomic percentage of C of about 0.5-2%.

11. A FinFET, comprising:
a semiconductor substrate;
a punch-through stopper layer disposed on the semiconductor substrate;
a semiconductor fin disposed on the punch-through stopper layer;
source and drain regions disposed on the punch-through stopper layer and being in contact with the semiconductor fin at opposite ends of the semiconductor fin, respectively; and
a gate stack disposed on top and side walls of the semiconductor fin and including a gate conductor and a gate dielectric interposed between the gate conductor and the semiconductor fin.

12. The FinFET of claim 11, wherein the punch-through stopper layer comprises an epitaxial layer on the semiconductor substrate, and is doped in-situ into a doping type contrary to that of the source and drain regions.

13. The FinFET of claim 12, wherein the punch-through stopper layer has a doping concentration of about 1e18-2e19/cm³.

14. The FinFET of claim 11, further comprising:
a gate spacer separating the gate conductor from the source and drain regions.

15. The FinFET of claim 11, further comprising:
an isolation layer separating the gate conductor from the punch-through stopper layer.

16. The FinFET of claim 11, wherein the semiconductor fin comprises a first semiconductor material, and the source and drain regions comprise a second semiconductor material different from the first semiconductor material, so that the source and drain regions apply stress to the semiconductor fin along a longitudinal direction of the semiconductor fin.

17. The FinFET of claim 16, wherein the FinFET is of p-type, and wherein the first semiconductor material comprise Si, and the second semiconductor material comprises SiGe, with an atomic percentage of Ge of about 15-75%.

18. The FinFET of claim 16, wherein the FinFET is of n-type, and wherein the first semiconductor material comprise Si, and the second semiconductor material comprises Si:C, with an atomic percentage of C of about 0.5-2%.
